(19) United States
(12) Patent Application Publication
(10) Pub. No.: US 2024/0224737 A1
(43) Pub. Date: Jul. 4, 2024

(54) LIGHT EXTRACTION SHEET FOR DISPLAY DEVICE AND MANUFACTURING METHOD THEREOF

(71) Applicant: LG Display Co., Ltd., Seoul (KR)

(72) Inventors: DaBin KIM, Gyeongsangnam-do (KR); KyungKook JANG, Gyeonggi-do (KR); SeungBum LEE, Gyeonggi-do (KR); SeungRyong LEE, Gyeonggi-do (KR)

(21) Appl. No.: 18/500,743

(22) Filed: Nov. 2, 2023

(30) Foreign Application Priority Data
Dec. 28, 2022 (KR) 10-2022-0187720

(51) Int. Cl. H10K 59/80; H01L 25/16; H01L 33/58

(52) U.S. Cl. CPC H10K 59/877; H01L 25/167; H01L 33/58; H01L 2933/0058; H01L 2933/0091

(57) ABSTRACT

Provided are a light extraction sheet for a display device and a manufacturing method thereof. The light extraction sheet is disposed on an emission area of the display device. The light extraction sheet includes a base layer formed of an insulating material. Transparent metal oxide crystals are formed on one or both surfaces of the base layer as a pattern of irregular curves. Total reflection occurring at the boundary of an emission layer is overcome, and light extraction efficiency is improved.

### CROSS REFERENCE TO RELATED APPLICATION

This application claims priority from Korean Patent Application No. 10-2022-0187720, filed on Dec. 28, 2022, which is hereby incorporated by reference for all purposes as if fully set forth herein.

### BACKGROUND

### Technical Field

Embodiments relate to a light extraction sheet for a display device and a manufacturing method thereof.

### Description of Related Art

In general, a liquid crystal display (LCD) device is manufactured by manufacturing an array substrate and a color filter substrate in an array substrate manufacturing process of forming thin-film transistors (TFTs) and pixel electrodes and a color filter manufacturing process of forming color filters and a common electrode, followed by a cell process of interposing liquid crystals between the two substrates.

However, the LCD device does not have a self-luminous element, and thus is required to have a separate light source to display an image on the basis of differences in transmittance. In this regard, a backlight unit having a built-in light source is disposed on the rear surface of an LCD panel.

Such backlight units are categorized as a direct-type backlight unit and an edge-type backlight unit depending on the position of a light source. The direct-type backlight unit is configured such that a light source is disposed below an LCD panel, whereby light emitted by the light source is directly supplied to the LCD panel. The edge-type backlight unit is configured such that a light guide plate is disposed below an LCD panel and at least one light source is disposed on at least one side of the light guide plate, whereby light emitted by the light source is indirectly supplied to the LCD panel using the refraction and reflection of light by the light guide plate.

Here, as the light source of the backlight unit, fluorescent lamps such as a cold cathode fluorescent lamp (CCFL) and an external electrode fluorescent lamp (EEFL) have generally been used. However, along with the recent trend toward the thin profile and light weight of LCD devices, fluorescent lamps are being replaced by light-emitting diodes (LEDs) advantageous in terms of power consumption, weight, luminance, and the like.

In addition, a plurality of optical sheets is disposed between the light guide plate of the backlight unit and the LCD panel. Recently, a light conversion sheet including quantum dots is added in order to improve the transmittance of light generated by the light source.

### BRIEF SUMMARY

In the light conversion sheet including quantum dots, quantum dots and an inorganic or organic phosphor may be mixed together with a luminosity-enhancing agent. Thus, the light conversion sheet has the function of absorbing light emitted from a light guide plate and then generating light.

However, the light conversion sheet including quantum dots of the related art has a problem in that light generated by the emission layer may not be discharged externally and may be totally reflected into the emission layer due to the difference of the refractive index between the emission layer and a layer in contact with the emission layer. The light totally reflected in this manner may be trapped in the emission layer, and this phenomenon is referred to as the waveguide mode.

As described above, a display device in the related art has a problem in that the luminance thereof is lowered due to the presence of the waveguide mode. In addition, the waveguide mode disadvantageously increases the amount of power consumed by a display device to generate light at a predetermined luminance.

Accordingly, the inventors of this specification invented a light extraction sheet for a display device and a manufacturing method thereof, the light extraction sheet being configured to overcome the various technical problems of the related art including the problem of total reflection occurring at the boundary of an emission layer. Various embodiments of a light extraction sheet for a display device may improve luminous efficiency by overcoming the above-mentioned problem.

Embodiments may provide a light extraction sheet for a display device and a manufacturing method thereof, in which the light extraction sheet having increased surface roughness may be provided on the surface of an emission area in contact with an emission layer in order to extract light in the waveguide mode in which light would otherwise be totally reflected at the boundary of the emission layer and trapped in the emission layer, thereby improving the luminance of the display device and reducing the power consumption of the display device.

Embodiments may provide a light extraction sheet for a display device disposed on an emission area of the display device. The light extraction sheet may include: a base layer formed of an insulating material; and transparent metal oxide crystals formed on one or both surfaces of the base layer as a pattern of irregular curves.

Embodiments may provide a manufacturing method of a light extraction sheet for a display device, the light extraction sheet being disposed on an emission area of the display device. The manufacturing method may include: forming (or preparing) a base layer formed of an insulating material; and forming (or obtaining) transparent metal oxide crystals on one or both surfaces of the base layer as a pattern of irregular curves.

In the light extraction sheet for a display device and the manufacturing method thereof according to embodiments, the light extraction sheet having increased surface roughness may be provided on the surface of the emission area in contact with the emission layer in order to extract light in the waveguide mode in which light would otherwise be totally reflected at the boundary of the emission layer and trapped in the emission layer, thereby improving the luminance of the display device.

In the light extraction sheet for a display device and the manufacturing method thereof according to embodiments, power consumption may be reduced due to the improved light extraction efficiency, thereby enabling low power driving.

### BRIEF DESCRIPTION OF THE SEVERAL VIEWS OF THE DRAWINGS

The above and other objectives, features, and advantages of the present disclosure will be more clearly understood from the following detailed description, taken in conjunction with the accompanying drawings, in which:

FIG. 1 is a perspective diagram schematically illustrating a light extraction sheet according to an embodiment;

FIG. 2 is a side diagram of the light extraction sheet illustrated in FIG. 1;

FIG. 3 is a side diagram schematically illustrating a light extraction sheet according to another embodiment;

FIG. 4 is a side diagram schematically illustrating a light extraction sheet according to another embodiment;

FIG. 5 is a flowchart illustrating a manufacturing method of a light extraction sheet according to an embodiment;

FIG. 6 is a set of AFM images captured from the surfaces of light extraction sheets manufactured according to Examples 1 to 3;

FIG. 7A is a graph illustrating light transmittances according to light incidence angles in a display device without a light extraction sheet;

FIG. 7B is a graph illustrating light transmittances according to light incidence angles in a display device including a light extraction sheet manufactured according to Example 1;

FIG. 8 is a diagram schematically illustrating an example in which a light extraction sheet according to an embodiment is applied to a QD sheet of a mini-LED display device;

FIG. 9 is a diagram schematically illustrating an example in which a light extraction sheet according to an embodiment is applied to a micro-LED display device; and

FIG. 10 is a diagram schematically illustrating an example in which a light extraction sheet according to an embodiment is applied to an OLED display device.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “made up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, a variety of embodiments will be described in detail with reference to the accompanying drawings.

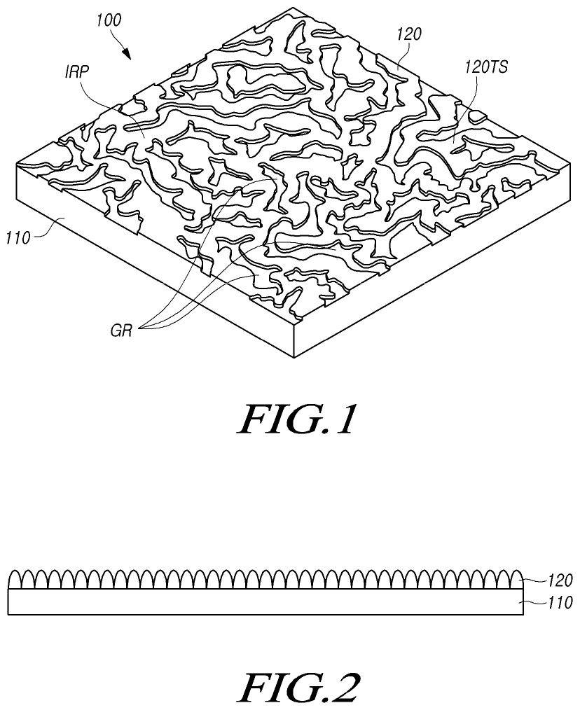

FIG. 1 is a perspective diagram schematically illustrating a light extraction sheet according to an embodiment, and FIG. 2 is a side diagram of the light extraction sheet illustrated in FIG. 1.

Referring to FIGS. 1 and 2, a light extraction sheet 100 is disposed on an emission area of a display device. The light extraction sheet 100 may include a base layer 110 and metal oxide crystals 120 on the base layer 110. Here, a display device in which the light extraction sheet 100 is used may include, but not limited to, a micro-light-emitting diode (LED) display device, a mini-LED display device, an organic electroluminescent display device or organic light-emitting display (OLED) device, a liquid crystal display (LCD) device, and a quantum dot light-emitting display (QLED) device.

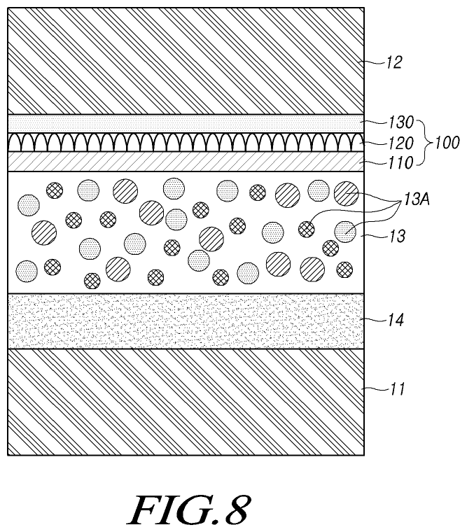

In the following embodiments, for convenience of description, the light extraction sheet 100 will be described as being located on or above the top surface of (hereinafter, referred to as “above”) the emission area of each of display devices illustrated in FIGS. 8 to 10 on the assumption that the emission area faces upward in the figures.

The base layer 110 constituting the base of the light extraction sheet 100 may be implemented as a transparent substrate having flat top and bottom portions, with the thickness thereof being in the range of about 0.5 to 2 m.

The base layer 110 may be formed of an insulating material. For example, the base layer 110 may be formed of an inorganic insulating material including one selected from among SiNx, SiOx, SiOxNv, AlOx, ZnSnOx, ITO, ZnO, IZO, ZnS, and MgO.

In this manner, when the base layer 110 is formed of an insulating material, direct contact between the display device and the metal oxide crystals 120 to be described below may be prevented, and thus other conductive components may be prevented from being influenced. In addition, it is possible to prevent moisture from infiltrating the emission area through the base layer 110, thereby reducing the water vapor transmission ratio (WVTR).

In addition, the transparent metal oxide crystals 120 may be formed on one surface of the base layer 110 as a pattern of irregular curves. For example, the metal oxide crystals 120 may protrude from one surface of the base layer 110 as a pattern of curves. Due to this shape of the metal oxide crystals 120, grooves such as creases may be formed between the metal oxide crystals 120.

As shown in FIG. 1, the metal oxide crystals 120 form irregular patterns IRP. The irregular patterns IRP includes a plurality of grooves GR. The groove of the plurality extends towards the base layer 110. In some embodiments, at least one of the grooves of the plurality exposes an upper surface or a top surface of the base layer 110. For example, as shown in FIG. 4, some grooves may expose a first surface FS (which is equivalent to the upper surface or the top surface) of the base layer 110. Some grooves GR may extend from a top surface 120TS of the metal oxide crystals 120 to expose the first surface FS of the base layer 110. The other grooves may extend from a top surface 120TS of the metal oxide crystals 120 towards the base layer 110 but may not extend so as to expose the first surface FS of the base layer 110.

In some embodiments, the first insulation layer 131 contacts the plurality of grooves GR and extends into the plurality of grooves GR to fill the plurality of grooves GR of the first metal oxide crystals 121. Similarly, the second insulation layer 132 contacts the plurality of grooves GR and extends into the plurality of grooves GR to fill the plurality of grooves GR of the second metal oxide crystals 122.

The irregular patterns IRP include various random patterns. The patterns may include a jagged pattern, a porous pattern, or any type of random patterns that have surface roughness.

The first transparent metal oxide crystals 121 on the first surface FS of the base layer 110 includes first irregular patterns. Similarly, the second transparent metal oxide crystals 122 on the second surface SS of the base layer 110 includes second irregular patterns. In one embodiment, the first irregular patterns and the second irregular patterns include different irregular patterns from each other.

Although the transparent metal oxide crystals 120 are described and illustrated as being disposed above the base layer 110 in embodiments, the transparent metal oxide crystals 120 may be disposed on or below the bottom surface of (hereinafter, referred to as “below”) the base layer 110.

The transparent metal oxide of the metal oxide crystals 120 may be one selected from among TiO₂, ZnO₂, and SnO₂. TiO₂, ZnO₂, and SnO₂ have a relatively high energy band gap, and thus may have superior efficiency when used in a photoelectrode.

The transparent metal oxide crystals 120 may be formed on the base layer 110 using sol-gel synthesis. Sol-gel synthesis is a typical process of synthesizing metal oxides, e.g., ceramics. Sol-gel synthesis is advantageous in terms of simple processing and a high production efficiency due to a low processing temperature, compared to chemical vapor deposition (CVD).

Sol-gel synthesis may also have advantages in that uniform mixing is possible even in a multi-component system and new compositions may be easily synthesized. In addition, sol-gel synthesis may control the sizes of the metal oxide crystals 120 synthesized by controlling the pH of a sol-gel solution, the type and amount of a solvent, the amount of a solute, the environment such as temperature, and the like. A specific method of manufacturing a metal oxide using sol-gel synthesis will be described below.

As described above, as the transparent metal oxide crystals 120 is disposed on the base layer 110, the roughness of the surface of the base layer 110 may be increased. The surface of the base layer 110 having the increased roughness scatters light output from the emission area, and thus total reflection occurring at the boundary of an emission layer that emits light may be reduced. Since the reduced total reflection causes light extraction in the waveguide mode, the luminance of the display device may be improved while power consumption of the display device may be simultaneously reduced.

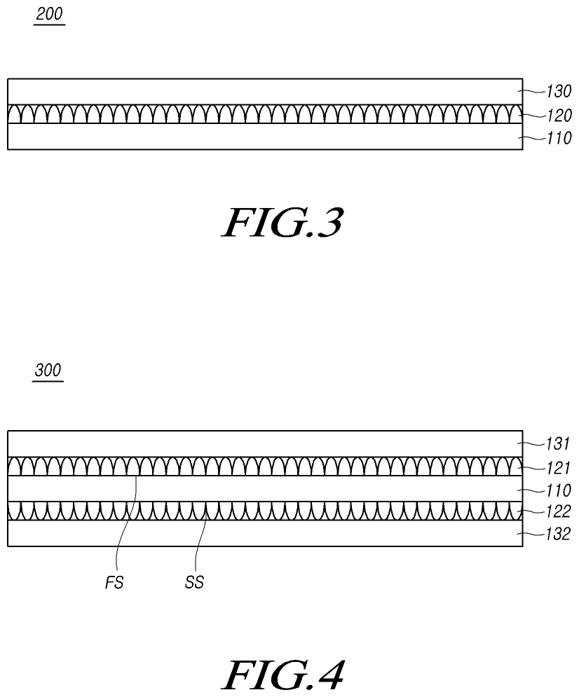

FIG. 3 is a side diagram schematically illustrating a light extraction sheet according to another embodiment. In the description of the present embodiment, features of the present embodiment different from those of the foregoing embodiment will be mainly described.

Referring to FIG. 3, a light extraction sheet 200 may include a base layer 110, metal oxide crystals 120, and an insulating layer 130. Here, the base layer 110 and the metal oxide crystals 120 are the same as those described above in the foregoing embodiment and thus a description thereof will be omitted.

The insulating layer 130 according to embodiments may be disposed on one surface of the base layer 110 to cover or encase the metal oxide crystals 120. For example, when the metal oxide crystals 120 are disposed on the base layer 110, the insulating layer 130 may be disposed above the base layer 110 such that the metal oxide crystals 120 are interposed between the base layer 110 and the insulating layer 130.

The insulating layer 130 may be formed of an inorganic insulating material including one selected from among SiNx, SiOx, SiOxNv, AlOx, ZnSnOx, ITO, ZnO, IZO, ZnS, and MgO. That is, the insulating layer 130 may be formed of the same material as the base layer 110, and may be deposited on the base layer 110 by sputtering.

As the insulating layer 130 is provided such that the metal oxide crystals 120 are interposed between the base layer 110 and the insulating layer 130, foreign matter and moisture may be prevented from infiltrating the metal oxide crystals 120. Since the insulating layer 130 may prevent moisture from infiltrating the emission area together with the base layer 110, the WVTR may be more effectively reduced.

FIG. 4 is a side diagram schematically illustrating a light extraction sheet according to another embodiment. In the description of the present embodiment, features of the present embodiment different from those of the foregoing embodiment will be mainly described.

A light extraction sheet 300 according to embodiments may include a base layer 110, metal oxide crystals 121 and 122, and insulating layers 131 and 132. Specifically, referring to FIG. 4, the light extraction sheet 300 may include: the base layer 110; the first insulating layer 131 and the second insulating layer 132 disposed above and below the base layer 110, respectively; the first metal oxide crystals 121 interposed between the base layer 110 and the first insulating layer 131; and the second metal oxide crystals 122 interposed between the base layer 110 and the second insulating layer 132. That is, the base layer 110 has a first surface FS and a second surface SS opposite the first surface FS. The first metal oxide crystals 121 are on the first surface FS of the base layer 110 and the second metal oxide crystals 122 are on the second surface SS of the base layer 110.

When the light extraction sheet 300 further includes the second metal oxide crystals 122 and the second insulating layer 132 below the base layer 110 as described above, the surface roughness of the base layer 110 may be further increased. Thus, a greater amount of light may be extracted in the waveguide mode caused by total reflection, thereby further improving the luminance of the display device.

In addition, in some embodiments, the first metal oxide crystals 121 and the second metal oxide crystals 122 may have the same size. In other embodiments, preferably, the size of the first metal oxide crystals 121 may differ from the size of the second metal oxide crystals 122. In this case, the upper portion and the lower portion of the base layer 110 have different roughness values, and thus light may be more efficiently extracted.

FIG. 5 is a flowchart illustrating a manufacturing method of a light extraction sheet according to an embodiment.

Referring to FIG. 5, a light extraction sheet manufacturing method S100 may include: a process S110 of forming a base layer (or preparing a base layer); a process S120 of obtaining transparent metal oxide crystals; and a process S130 of depositing an insulating layer.

In the process S110 of forming/preparing the base layer, the base layer 110 formed of an insulating material may be prepared. For example, the base layer 110 having the shape of a flat plate may be manufactured from an inorganic insulating material including one selected from among SiNx, SiOx, SiOxNv, AlOx, ZnSnOx, ITO, ZnO, IZO, ZnS, and MgO.

In the process S120 of obtaining the transparent metal oxide crystals, the transparent metal oxide crystals 120 having a pattern of irregular curves may be obtained on one or both surfaces of the base layer 110. For example, the transparent metal oxide may include one selected from among TiO₂, ZnO₂, and SnO₂, and may be formed on one or both surfaces of the base layer 110 using sol-gel synthesis.

Specifically, the process S120 of obtaining the transparent metal oxide crystals using sol-gel synthesis may include: a process of applying a sol-gel solution by adding a metal precursor to a mixture of a first solvent and a second solvent having different evaporation rates; a process of stirring the sol-gel solution at a temperature of 50 to 70° C. for 20 to 40 minutes; a process of coating one or both surfaces of the base layer 110 with the sol-gel solution by spin coating or slit coating; a process of annealing the base layer 110 coated with the sol-gel solution while increasing the temperature from 100° C. to 400° C. at a temperature growth rate of 10 to 30° C./min; and a process of sintering the annealed base layer 110 at a temperature of 450 to 550° C. for 20 to 40 minutes.

Since the sol-gel solution is manufactured using the first solvent and the second solvent having different evaporation rates, one solvent having the faster evaporation rate may evaporate during the annealing process and the other solvent having the slower evaporation rate may evaporate partially or remain during the annealing process, whereby the metal oxide crystals 120 may be obtained.

The metal precursor according to embodiments may include at least one selected from the group consisting of a zinc precursor, a titanium precursor, and a tin precursor. For example, the zinc precursor may include zinc acetate dehydrate. The titanium precursor may include titanium oxyacetylacetonate or titanium isopropoxide. The tin precursor may include tin acetate or tin acetylacetonate.

According to embodiments, the first solvent may include ethanolamine or diethanolamine, while the second solvent may include one selected from among 2-methoxyethanol, ethanol, methanol, and isopropyl alcohol (2-propanol).

That is, the second solvent may be comprised of a material having a faster evaporation rate than the first solvent. Due to these features of the first solvent and the second solvent, when the base layer 110 coated with the sol-gel solution is annealed in a condition of different temperature growth rates, the second solvent having the faster evaporation rate evaporates and the second solvent evaporates partially or remains, thereby forming the crystals 120 protruding in the shape of curves from the base layer 110. Due to the protruding crystals 120, grooves such as creates may be formed between the crystals 120, whereby the roughness of the base layer 110 may be adjusted.

In the process S130 of depositing the insulating layer, one or more insulating layers 130 (131, 132) including one selected from among SiNx, SiOx, SiOxNv, AlOx, ZnSnOx, ITO, ZnO, IZO, ZnS, and MgO may be formed on one or both surfaces of the base layer 110 by sputtering, thereby covering the metal oxide crystals 120 formed on one or both surfaces of the base layer 110.

Since the insulating layer 130 is deposited on one surface of the base layer 110 by sputtering instead of using an adhesive, the problem of total reflection caused by the difference of the refractive index between the adhesive and the base layer 110 may be prevented.

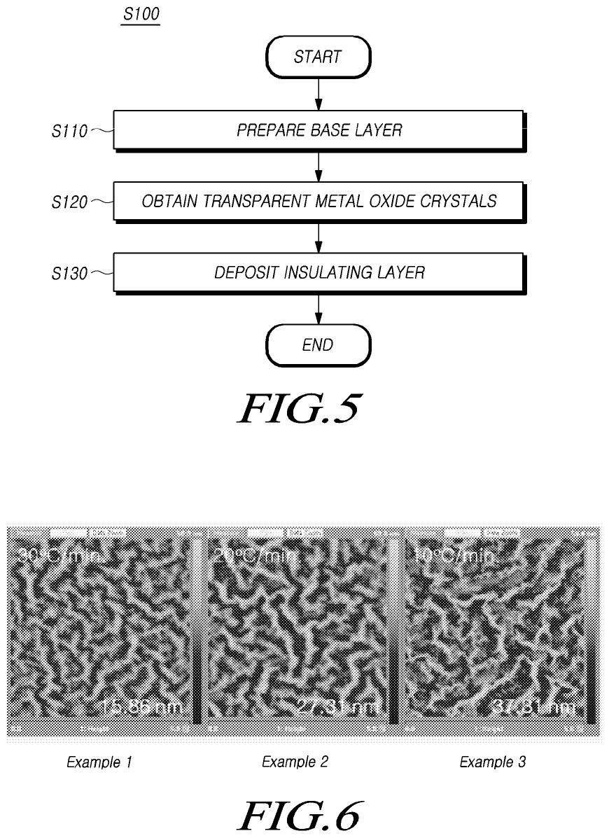

FIG. 6 is a set of atomic force microscopy (AFM) images captured from the surfaces of light extraction sheets manufactured according to Examples 1 to 3.

### Example 1

A sol-gel solution was manufactured by adding a zinc acetate [Zn(CH₃COO)₂·2H₂O] precursor to a mixture of 0.75 M ethanolamine and 0.75 M 2-methoxyethanol. The sol-gel solution was stirred at 60° C. for 30 minutes and then was applied to a SiNx substrate by spin coating. The substrate coated with the sol-gel solution was annealed by increasing the temperature from 100° C. to 400° C. at a temperature growth rate of 30° C./min, thereby forming ZnO₂ crystals on the substrate. Afterwards, additional sintering was performed at a temperature of 500° C. for 30 minutes in order to sinter the ZnO₂ crystals.

### Example 2

A sol-gel solution was manufactured by adding a zinc acetate [Zn(CH₃COO)₂·2H₂O] precursor to a mixture of 0.75 M ethanolamine and 0.75 M 2-methoxyethanol. The sol-gel solution was stirred at 60° C. for 30 minutes and then was applied to a SiNx substrate by spin coating. The substrate coated with the sol-gel solution was annealed by increasing the temperature from 100° C. to 400° C. at a temperature growth rate of 20° C./min, thereby forming ZnO₂ crystals on the substrate. Afterwards, additional sintering was performed at a temperature of 500° C. for 30 minutes in order to sinter the ZnO₂ crystals.

### Example 3

A sol-gel solution was manufactured by adding a zinc acetate [Zn(CH₃COO)₂·2H₂O] precursor to a mixture of 0.75 M ethanolamine and 0.75 M 2-methoxyethanol. The sol-gel solution was stirred at 60° C. for 30 minutes and then was applied to a SiNx substrate by spin coating. The substrate coated with the sol-gel solution was annealed by increasing the temperature from 100° C. to 400° C. at a temperature growth rate of 10° C./min, thereby forming ZnO₂ crystals on the substrate. Afterwards, additional sintering was performed at a temperature of 500° C. for 30 minutes in order to sinter the ZnO₂ crystals.

Comparing the structures of the images according to Examples 1 to 3 with reference to FIG. 6, it can be seen that when the temperature growth rate was lower, the widths of the grooves located between the ZnO₂ crystals were greater since a greater amount of ethanolamine evaporated. Thus, when the temperature growth rate is adjusted, the sizes of the metal oxide crystals 120 may be controlled.

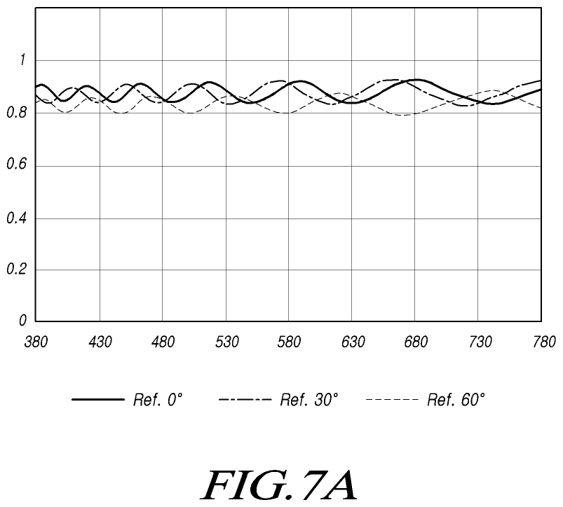

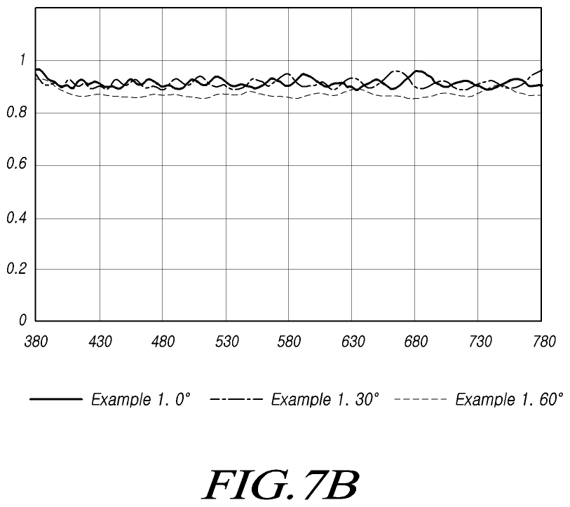

FIG. 7A is a graph illustrating light transmittances according to light incidence angles in a display device without a light extraction sheet. The light transmittances according to the light incidence angles of 0°, 30°, and 60° in the graph of FIG. 7A will be summarized as in Table 1 below.

TABLE 1

| Incidence angle | 0° | 30° | 60° |
|---|---|---|---|
| Light Transmittance | 88.0% | 87.9% | 84.0% |

FIG. 7B is a graph illustrating light transmittances according to light incidence angles in a display device including a light extraction sheet manufactured according to Example 1. The light transmittances according to the light incidence angles of 0°, 30°, and 60° in the graph of FIG. 7B will be summarized as in Table 2 below.

TABLE 2

| Incidence angle | 0° | 30° | 60° |
|---|---|---|---|
| Light Transmittance | 91.5% | 91.4% | 87.4% |

Comparing Table 1 and Table 2, it can be seen that the light transmittance of the display device including the light extraction sheet 100 was improved than that of the display device without the light extraction sheet 100.

FIG. 8 is a diagram schematically illustrating an example in which a light extraction sheet according to an embodiment is applied to a QD sheet of a mini-LED display device.

A QD sheet of a mini-LED display device may include: a first substrate 11 formed of polyethylene terephthalate (PET); a second substrate 12 formed of PET and disposed above the first substrate 11; a quantum emission layer 13 disposed between the first substrate 11 and the second substrate 12, including a plurality of quantum dots 13A; and a barrier layer 14 disposed between the first substrate 11 and the quantum emission layer 13. In addition, the light extraction sheet 100 may be disposed between the quantum emission layer 13 and the second substrate 12 to scatter light generated by the quantum emission layer 13, thereby preventing total reflection from occurring at the boundary of the quantum emission layer 13. Accordingly, light extraction efficiency may be improved and thus luminance may be advantageously improved.

For example, the QD sheet may be disposed between a light guide plate of a backlight unit using blue light-emitting diodes (LEDs) as a light source and optical sheets. Blue light traveling through the light guide plate may be converted into red light and green light by red quantum dots and green quantum dots of the quantum emission layer 13. Accordingly, the blue light, the red light, and the green light may be mixed in the QD sheet, thereby creating white light.

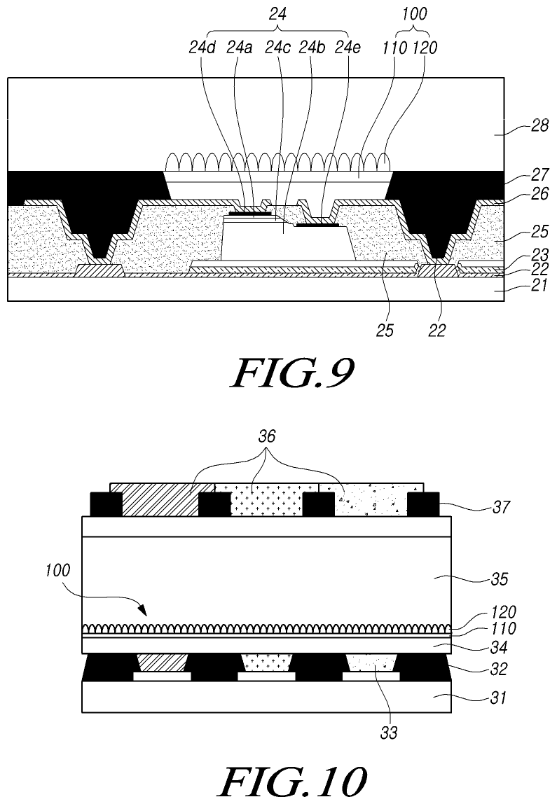

FIG. 9 is a diagram schematically illustrating an example in which a light extraction sheet according to an embodiment is applied to a micro-LED display device.

Referring to FIG. 9, the display device includes a metal layer 22 disposed on a base substrate 21, a protective layer 23 disposed on the metal layer 22, a micro LED 24 disposed on the protective layer 23, a transparent planarization layer 25 covering a portion of the micro LED 24, a pixel electrode 26 disposed on the transparent planarization layer 25 and electrically connected to the micro LED 24, a light extraction sheet 100 disposed on top of the micro LED 24, a black matrix 27 covering a side portion of the light extraction sheet 100, and a encapsulation layer 28 disposed on top of the light extraction sheet 100 and the black matrix 27.

The base substrate 21 may be formed of a glass material.

The metal layer 22 is a layer on which metal for forming TFTs, wiring and the like is disposed. The metal layer 22 may be disposed on the base substrate 21.

The micro LED 24 may include a first semiconductor layer 24a, a second semiconductor layer 24b, and an active layer 24c. The first semiconductor layer 24a may be disposed over one portion of the second semiconductor layer 24b, exposing at least a portion of the other portion of the second semiconductor layer 24b. An active layer 24c may be interposed between the first semiconductor layer 24a and the second semiconductor layer 24b. The active layer 24c may also be referred to as an emission layer.

The micro LED 24 may further include a first electrode 24d and a second electrode 24e. The first electrode 24d may be disposed on the first semiconductor layer 24a and may be electrically connected to the first semiconductor layer 24a. The second electrode 24e may be disposed on the exposed second semiconductor layer 24b and may be electrically connected to the second semiconductor layer 24b.

The first electrode 24d and the second electrode 24e may be spaced apart from each other by a predetermined distance. The first electrode 24d and the second electrode 24e may include an oxide-based transparent conductive material, such as titanium dioxide (TiO₂), aluminum zinc oxide (AZO), zinc oxide (ZnO), indium tin oxide (ITO), gallium zinc oxide (GZO), indium zinc oxide (IZO), and the like, or include PEDOT(poly(3,4-ethylenedioxythiophene)): PSS(poly(styrenesulfonate))-based conductive material, graphene, metallic wire, and the like.

The transparent planarization layer 25 may cover a portion of the side and top of the micro LED 24.

The pixel electrode 26 may be disposed on the transparent planarization layer 25. For example, the pixel electrode 26 may be electrically connected to the first electrode 24d of the micro LED 24 through a hole in the transparent planarization layer 25.

The black matrix 27 is used to define a light-emitting area and may be disposed on the pixel electrode 26. The black matrix 27 may be formed so as not to shield the micro LED 24.

The encapsulation layer 28 is flatten the height difference caused by the elements disposed below and prevent moisture and foreign substances from penetrating into the interior. The encapsulation layer 28 may be disposed on top of the light extraction sheet 100 and the black matrix 27.

The light extraction sheet 100 may be disposed on a transparent planarization layer 25 between black matrices 27 of the micro-LED 24. Accordingly, light generated by the micro-LED 24 may be scattered to provide a wider field of view.

FIG. 10 is a diagram schematically illustrating an example in which a light extraction sheet according to an embodiment is applied to an OLED display device.

Referring to FIG. 10, the light extraction sheet 100 may be used in a color filter on encapsulation (COE) layer of an OLED display device. The COE layer may include disposed on a base substrate 31 and includes a bank layer 32 having a plurality of openings, A plurality of OELD elements 33 disposed in the opening formed in the bank layer 32, an encapsulation layer 34 covering the bank layer 32 and the OELD elements 33, a touch sensor on encapsulation (TOE) layer 35 where touch sensor metal such as the touch line is located, a color filter layer (CFL) 36 converting white light generated by the OLED elements 33 into different colors of light. And the CFL 36 may be divided by a black matrix 37.

In addition, the light extraction sheet 100 may be disposed between the OLED elements 33 and the CFL 36 to scatter light generated by the OLED elements 33, thereby improving luminous reflectance in the TOE layer.

The above-described embodiments of the present disclosure will be briefly reviewed as follows.

Embodiments may provide a light extraction sheet 100 for a display device disposed on an emission area of the display device. The light extraction sheet 100 may include: a base layer 110 formed of an insulating material; and transparent metal oxide crystals 120 formed on one or both surfaces of the base layer 110 as a pattern of irregular curves.

According to embodiments, the base layer 110 may be formed of an inorganic insulating material including one selected from among SiNx, SiOx, SiOxNv, AlOx, ZnSnOx, ITO, ZnO, IZO, ZnS, and MgO.

According to embodiments, the transparent metal oxide may include one selected from among TiO₂, ZnO₂, and SnO₂.

According to embodiments, the metal oxide crystals 120 may be formed on the base layer 110 using sol-gel synthesis.

According to embodiments, the light extraction sheet 100 may further include one or more insulating layers 130 (131, 132) disposed on one or both surfaces of the base layer 110 to cover the metal oxide crystals 120.

According to embodiments, the insulating layer 130 may be formed of an inorganic insulating material including one selected from among SiNx, SiOx, SiOxNv, AlOx, ZnSnOx, ITO, ZnO, IZO, ZnS, and MgO.

According to embodiments, the metal oxide crystals 120 may be disposed above and below the base layer 110. The size of the metal oxide crystals located above the base layer 110 may differ from the size of the metal oxide crystals located below the base layer 110.

According to embodiments, the display device may include one selected from among a micro-light-emitting diode (micro-LED) display device, a mini-LED display device, an organic light-emitting display (OLED) device, a liquid crystal display (LCD) device, and a quantum dot light-emitting display (QLED) device.

Embodiments may provide a manufacturing method S100 of a light extraction sheet for a display device, the light extraction sheet being disposed on an emission area of the display device. The manufacturing method S100 may include: a process S110 of forming a base layer formed of an insulating material; and a process S120 of forming transparent metal oxide crystals on one or both surfaces of the base layer 110 as a pattern of irregular curves.

According to embodiments, the base layer 110 may be formed of an inorganic insulating material including one selected from among SiNx, SiOx, SiOxNv, AlOx, ZnSnOx, ITO, ZnO, IZO, ZnS, and MgO.

According to embodiments, the transparent metal oxide may include one selected from among TiO₂, ZnO₂, and SnO₂.

According to embodiments, the process S120 of obtaining the transparent metal oxide crystals may include: a process of applying a sol-gel solution by adding a metal precursor to a mixture of a first solvent and a second solvent having different evaporation rates; a process of stirring the sol-gel solution at a temperature of 50 to 70° C. for 20 to 40 minutes; a process of coating one or both surfaces of the base layer 110 with the sol-gel solution by spin coating or slit coating; and a process of annealing the base layer 110 coated with the sol-gel solution while increasing the temperature from 100° C. to 400° C. at a temperature growth rate of 10 to 30° C./min.

According to embodiments, the metal precursor may include at least one selected from the group consisting of a zinc precursor, a titanium precursor, and a tin precursor.

According to embodiments, the zinc precursor may include zinc acetate dehydrate.

According to embodiments, the titanium precursor may include titanium oxyacetylacetonate or titanium isopropoxide.

According to embodiments, the tin precursor may include tin acetate or tin acetylacetonate.

According to embodiments, the first solvent may include ethanolamine or diethanolamine, while the second solvent may include one selected from among 2-methoxyethanol, ethanol, methanol, and isopropyl alcohol (2-propanol).

According to embodiments, the manufacturing method may further include a process of sintering the annealed base layer 110 at a temperature of 450 to 550° C. for 20 to 40 minutes.

According to embodiments, the manufacturing method may further include a process S130 of depositing one or more insulating layers to cover the metal oxide crystals 120 formed on one or both surfaces of the base layer 110.

According to embodiments, the process S130 of depositing the insulating layer may include a process of depositing one or more insulating layers 130 (131, 132) on one or both surfaces of the base layer 110 by sputtering. The insulating layer 130 may include one selected from among SiNx, SiOx, SiOxNv, AlOx, ZnSnOx, ITO, ZnO, IZO, ZnS, and MgO.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light extraction sheet for a display device disposed on an emission area of the display device, the light extraction sheet comprising:
a base layer comprising an insulating material; and
transparent metal oxide crystals provided on one or both surfaces of the base layer as a pattern of irregular curves.

2. The light extraction sheet according to claim 1, wherein the base layer comprises an inorganic insulating material comprising one selected from among SiNx, SiOx, SiOxNv, AlOx, ZnSnOx, ITO, ZnO, IZO, ZnS, and MgO.

3. The light extraction sheet according to claim 1, wherein the transparent metal oxide comprises one selected from among TiO₂, ZnO₂, and SnO₂.

4. The light extraction sheet according to claim 1, further comprising one or more insulating layers disposed on one or both surfaces of the base layer to cover the metal oxide crystals.

5. The light extraction sheet according to claim 4, wherein the insulating layer comprises an inorganic insulating material comprising one selected from among SiNx, SiOx, SiOxNv, AlOx, ZnSnOx, ITO, ZnO, IZO, ZnS, and MgO.

6. The light extraction sheet according to claim 4, wherein the metal oxide crystals are disposed above and below the base layer, the size of the metal oxide crystals located above the base layer being different from the size of the metal oxide crystals located below the base layer.

7. A manufacturing method of a light extraction sheet for a display device, the light extraction sheet disposed on an emission area of the display device, and comprising:
forming a base layer comprising an insulating material; and
forming metal oxide crystals on one or both surfaces of the base layer as a pattern of irregular curves.

8. The manufacturing method according to claim 7, wherein the base layer comprises an inorganic insulating material comprising one selected from among SiNx, SiOx, SiOxNv, AlOx, ZnSnOx, ITO, ZnO, IZO, ZnS, and MgO.

9. The manufacturing method according to claim 7, wherein the metal oxide comprises one selected from among TiO₂, ZnO₂, and SnO₂.

10. The manufacturing method according to claim 7, wherein the obtaining of the metal oxide crystals comprises:
applying a sol-gel solution by adding a metal precursor to a mixture of a first solvent and a second solvent having different evaporation rates;
stirring the sol-gel solution at a temperature of 50 to 70° C. for 20 to 40 minutes;
coating one or both surfaces of the base layer with the sol-gel solution by spin coating or slit coating; and
annealing the base layer coated with the sol-gel solution while increasing a temperature from 100° C. to 400° C. at a temperature growth rate of 10 to 30° C./min.

11. The manufacturing method according to claim 10, wherein the metal precursor comprises at least one selected from a group consisting of a zinc precursor, a titanium precursor, and a tin precursor.

12. The manufacturing method according to claim 11, wherein the zinc precursor comprises zinc acetate dehydrate.

13. The manufacturing method according to claim 11, wherein the titanium precursor comprises titanium oxyacetylacetonate or titanium isopropoxide.

14. The manufacturing method according to claim 11, wherein the tin precursor comprises tin acetate or tin acetylacetonate.

15. The manufacturing method according to claim 10, wherein the first solvent comprises ethanolamine or diethanolamine, and
the second solvent comprises one selected from among 2-methoxyethanol, ethanol, methanol, and isopropyl alcohol (2-propanol).

16. The manufacturing method according to claim 7, further comprising sintering the annealed base layer at a temperature of 450 to 550° C. for 20 to 40 minutes.

17. The manufacturing method according to claim 7, further comprising depositing one or more insulating layers to cover the metal oxide crystals formed on one or both surfaces of the base layer.

18. The manufacturing method according to claim 17, wherein the deposition of the insulating layer comprises depositing one or more insulating layers on one or both surfaces of the base layer by sputtering, the one or more insulating layers comprising one selected from among SiNx, SiOx, SiOxNv, AlOx, ZnSnOx, ITO, ZnO, IZO, ZnS, and MgO.

19. The manufacturing method according to claim 7, wherein obtaining metal oxide crystals on one or both surfaces of the base layer as a pattern of irregular curves includes using sol-gel synthesis to the metal oxide crystals at the base layer.

20. The manufacturing method according to claim 7, wherein the metal oxide crystals are transparent metal oxide crystals.

21. A display device comprising:
a plurality of subpixels on a substrate;
an emission area overlapping with the plurality of subpixels; and
a light extraction sheet on the emission area, the light extraction sheet including:
a base layer including an insulating material, the base layer having a first surface and a second surface opposite the first surface; and
first transparent metal oxide crystals on the first surface of the base layer, the first transparent metal oxide crystals having first irregular patterns.

22. The display device according to claim 21, comprising:
second transparent metal oxide crystals on the second surface of the base layer, the second transparent metal oxide crystals having second irregular patterns.

23. The display device according to claim 22, wherein the first irregular patterns and the second irregular patterns are different from each other.

24. The display device according to claim 22, wherein the first irregular patterns include a plurality of grooves, each of the grooves of the plurality extending towards the base layer.

25. The display device according to claim 24, wherein at least one of the grooves of the plurality exposes the first surface of the base layer.

26. The display device according to claim 21, comprising:
a first insulation layer on the first transparent metal oxide crystals.

27. The display device according to claim 22, comprising:
a second insulation layer on the second transparent metal oxide crystals,
wherein the base layer is between the first insulation layer and the second insulation layer.

28. The display device according to claim 21, wherein the display device includes any device selected from among a micro-light-emitting diode display device, a mini-light-emitting diode display device, an organic light-emitting display device, a liquid crystal display device, and a quantum dot light-emitting display device.

29. The display device according to claim 26, wherein the first insulation layer contacts the plurality of grooves and extends into the plurality of grooves.
